(19) United States
(12) Patent Application Publication
(10) Pub. No.: US 2019/0310034 A1
(43) Pub. Date: Oct. 10, 2019

(54) FLOW RATE CONTROL METHOD, TEMPERATURE CONTROL METHOD, AND PROCESSING APPARATUS

(71) Applicant: Tokyo Electron Limited, Tokyo (JP)

(72) Inventors: Kei KOBAYASHI, Miyagi (JP); Takehiko ARITA, Miyagi (JP)

(21) Appl. No.: 16/371,466

(22) Filed: Apr. 1, 2019

(30) Foreign Application Priority Data
Apr. 5, 2018 (JP) 2018-073336

(51) Int. Cl. F28F 27/02; H01L 21/67; H01L 21/66; H01J 37/32; H01J 37/34

(52) U.S. Cl. CPC F28F 27/02; H01L 21/67109; H01L 21/67248; H01J 37/3497; H01L 22/30; H01J 37/32449; H01L 21/67253

(57) ABSTRACT

A method of controlling a flow rate of fluid flowing through a passage formed in a member of a system is provided. The system includes the member, a first pipe connected to one side of the passage, a second pipe connected to another side of the passage, a third pipe connecting the first pipe and the second pipe at a side opposite the passage, a bypass pipe connecting the first pipe and the second pipe at a location closer to the member relative to the third pipe, a first valve provided at the first pipe, a bypass valve provided at the bypass pipe, and a pump provided at the third pipe, which is configured to supply the fluid to the passage. The method includes controlling the first valve, controlling the bypass valve, and controlling an operating frequency of the pump.

### CROSS-REFERENCE TO RELATED APPLICATIONS

This patent application is based on and claims priority to Japanese Patent Application No. 2018-073336 filed on Apr. 5, 2018, the entire contents of which are incorporated herein by reference.

### TECHNICAL FIELD

The present disclosure generally relates to a flow rate control method, a temperature control method, and a processing apparatus.

### BACKGROUND

A chiller unit is provided with a pump for circulating fluid in a passage. An amount of fluid that is output from a pump per unit time (hereinafter referred to as a “flow rate”) is controlled by changing an operating frequency of the pump with an inverter.

For example, Patent Document 1 discloses a substrate processing apparatus that includes a processing vessel, a base in which a passage is formed, an electrostatic chuck, a chiller, a first passage, a second passage, a bypass passage, and a flow rate adjusting valve. The chiller and a coolant inlet of the base are connected via the first passage. The chiller and a coolant outlet of the base are connected via the second passage. The bypass passage branches off at a halfway point of the first passage, and is connected to the second passage at a halfway point of the second passage.

### CITATION LIST

### Patent Document

[Patent Document 1] Japanese Laid-open Patent Application Publication No. 2013-172013

### SUMMARY

In one aspect, the present disclosure aims at expanding a controllable range of a flow rate flowing through a passage formed inside a member.

According to one aspect of the present disclosure, a method of controlling a flow rate of fluid flowing through a passage formed in a member of a system is provided. The system includes the member, a first pipe connected to one side of the passage, a second pipe connected to another side of the passage, a third pipe connecting the first pipe and the second pipe at a side opposite the passage, a bypass pipe connecting the first pipe and the second pipe at a location closer to the member relative to the third pipe, a first valve provided at the first pipe, a bypass valve provided at the bypass pipe, and a pump provided at the third pipe, which is configured to supply the fluid to the passage. The method includes controlling the first valve; controlling the bypass valve; and controlling an operating frequency of the pump.

### BRIEF DESCRIPTION OF THE DRAWINGS

FIGS. 1A, 1B, 2A, and 2B are diagrams illustrating a configuration of a flow rate control system according to an embodiment and examples of operations of the flow rate control system;

FIG. 3 is a diagram illustrating an example of an operating frequency and states of valves in a flow rate control process according to the embodiment;

FIG. 4 is a flowchart illustrating an example of the flow rate control process according to the embodiment;

FIG. 5 illustrates a correlation table according to the embodiment representing a relationship between the operating frequency and a flow rate;

FIG. 6 illustrates a correlation table according to the embodiment representing a relationship between openings of the valves and a flow rate;

FIG. 7 is a diagram illustrating a configuration of a temperature control system according to the embodiment and examples of operations of the temperature control system;

FIG. 8 is a flowchart illustrating an example of the temperature control process according to the embodiment;

FIG. 9 illustrates a correlation table according to the embodiment indicating a relationship between a temperature and a flow rate;

FIG. 10 is a diagram illustrating a configuration of a processing apparatus according to a modified example of the embodiment; and

FIG. 11 is a diagram illustrating an example of an operating frequency and states of valves in a flow rate control process according to the modified example.

### DETAILED DESCRIPTION OF EMBODIMENTS

In the following, embodiments of the present disclosure will be described with reference to the drawings. Note that in the following descriptions and the drawings, elements having substantially identical features are given the same reference symbols and overlapping descriptions may be omitted.

[Configuration of Flow Rate Control System]

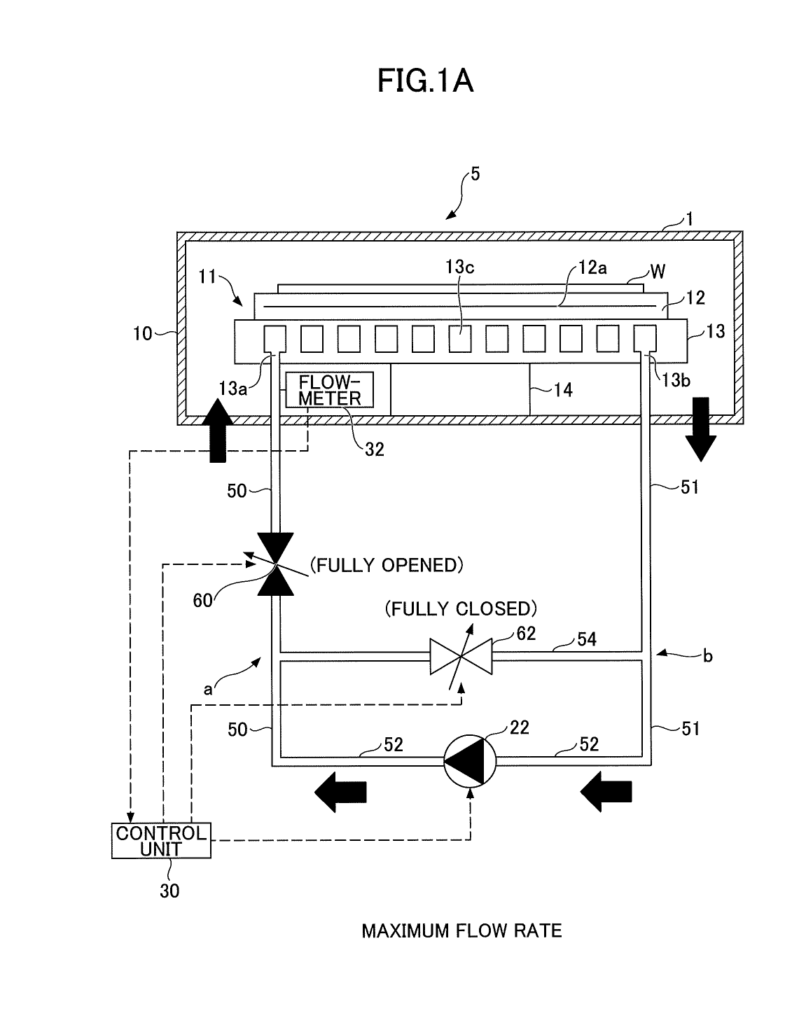

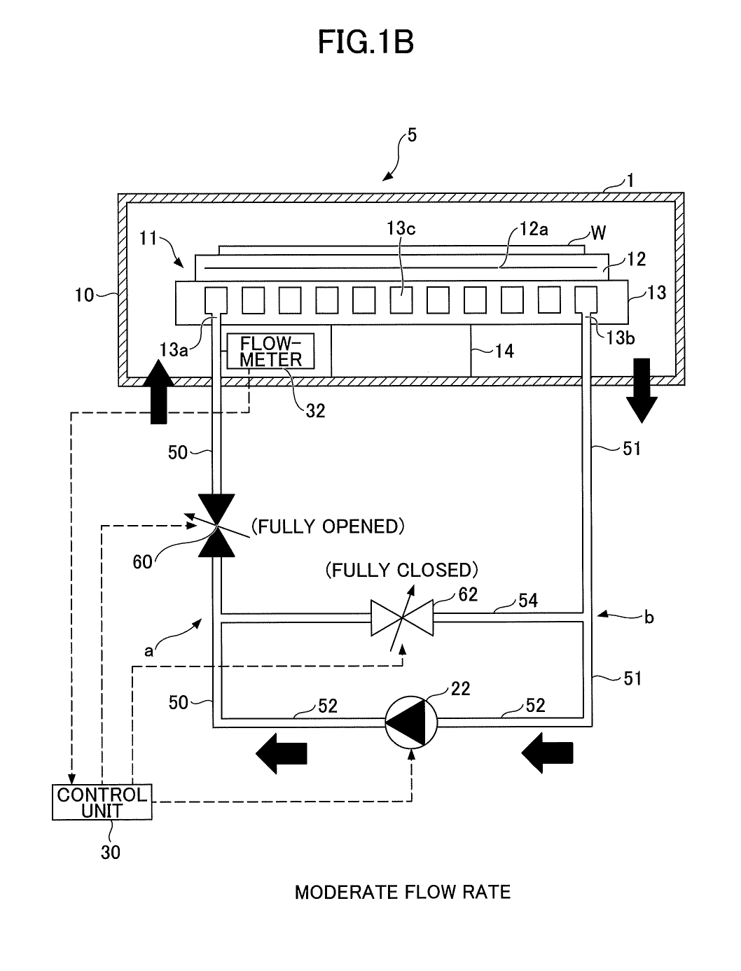

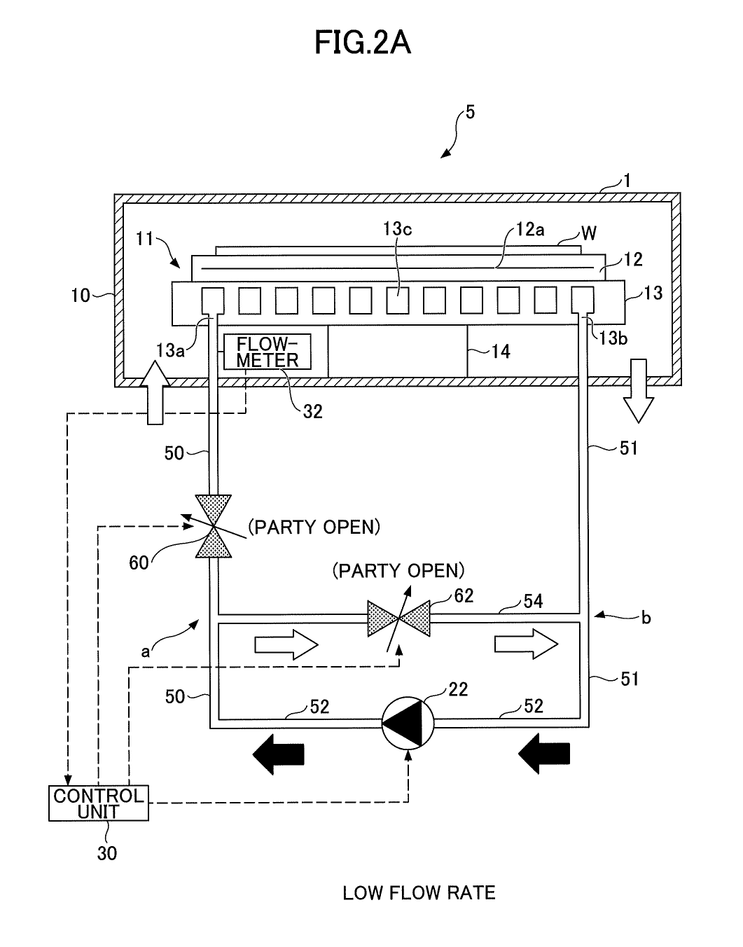

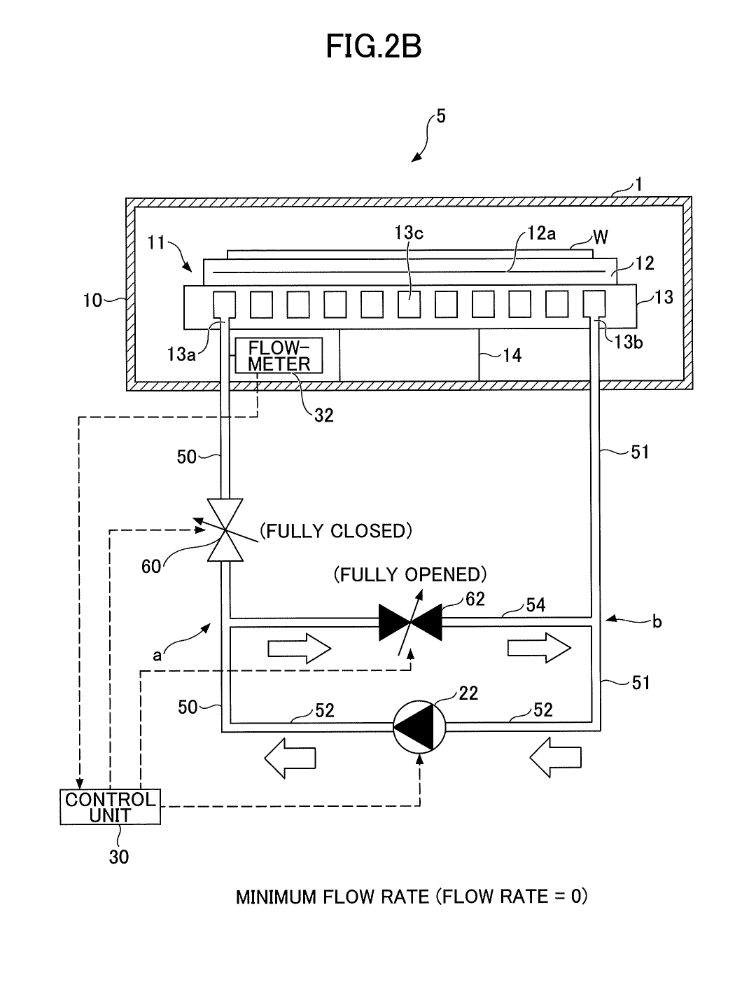

First, a configuration and examples of operations of a flow rate control system 5 according to an embodiment will be described with reference to FIGS. 1A to 2B. FIGS. 1A, 1B, 2A, and 2B are diagrams illustrating a configuration of the flow rate control system 5 according to the embodiment and examples of operations of the flow rate control system 5. As illustrated in FIG. 1A, the flow rate control system 5 includes a processing apparatus 1. The processing apparatus 1 is an apparatus for processing a wafer W. Heat processing, plasma processing, UV processing, and other processing are applied to the wafer W. Various types of processing, such as etching, deposition, cleaning, treatment, and asking, are included in processing of the wafer W.

The processing apparatus 1 includes a processing vessel 10. The processing vessel 10 is equipped with a stage 11 on which a wafer W is placed. The stage 11 includes an electrostatic chuck 12 and a base 13. The electrostatic chuck 12 is disposed on the base 13. The base 13 is supported by a supporting member 14. The electrostatic chuck 12 includes an electrode 12a. Voltage supplied from a direct-current (DC) power source is applied to the electrode 12a so that a wafer W becomes attracted electrostatically to the electrostatic chuck 12. Inside the base 13, a ring-shaped or vortex-shaped passage 13c is formed. The passage 13c is an example of a passage formed in a member.

The flow rate control system 5 includes pipes 50, 51, and 52, a bypass pipe 54, a valve A 60, a valve B 62, a pump 22, and a control unit 30. One end of the pipe 50 is connected to an inlet port 13a provided at an upstream side of the passage 13c. One end of the pipe 51 is connected to an outlet port 13b provided at a downstream side of the passage 13c. The other end of the pipe 50 and the other end of the pipe 51 are connected via the pipe 52. At a location closer to the base 13 relative to the pipe 52, the bypass pipe 54 connecting the pipe 50 and the pipe 52 are provided.

The valve A 60 is provided at the pipe 50. The valve B 62 is provided at the bypass pipe 54. The pump 22 for supplying fluid (coolant) to the passage 13c is provided at the pipe 52.

The pipe 50 is an example of a first pipe connected to one side of the passage 13c. The pipe 51 is an example of a second pipe connected to the other side of the passage 13c. The first pipe may be connected to one of an inlet of the passage 13c and an outlet of the passage 13c. The second pipe may be connected to the other one of the inlet of the passage 13c and the outlet of the passage 13c. The first pipe may be connected to the passage 13c at the upstream side of the passage 13c. The second pipe may be connected to the passage 13c at the downstream side of the passage 13c.

The pipe 52 is an example of a third pipe connecting the first pipe and the second pipe. The valve A 60 is an example of a first valve provided at either the first pipe or the second pipe. The valve B 62 is an example of a bypass valve provided at a bypass pipe.

A connecting point of the bypass pipe 54 and the pipe 50 is referred to as a “joint a”, and a connecting point of the bypass pipe 54 and the pipe 51 is referred to as a “joint b”.

The valve A 60 is provided at a point closer to the base 13 relative to the bypass pipe 54. The bypass pipe 54 causes a part or all of the coolant output from the pump 22 to bypass the passage 13c, by the valve A 60 and the valve B 62 being controlled.

The pump 22 controls a flow rate of the coolant to be output, by an inverter varying an operating frequency. After the coolant is output from the pump 22, the coolant branches at the joint a, and a ratio of coolant branching toward the pipe 50 to coolant branching toward the bypass pipe 54 is controlled in accordance with openings of the valve A 60 and the valve B 62.

At the joint b, the coolant that has entered from the pipe 50 to the passage 13c and has passed through the passage 13c joins the coolant that has passed through the bypass pipe 54, and returns to the pump 22. The coolant is output from the pump 22 again, and circulates in a path from the pipe 50 to the pipe 52 via the passage 13c and the pipe 51 or a path from the pipe 50 to the pipe 52 via the bypass pipe 54 and the pipe 51.

A flowmeter 32 is provided in a vicinity of the inlet port 13a. The flowmeter 32 measures a flow rate of coolant supplied to the passage 13c. Note that the flowmeter 32 may be provided in a vicinity of the outlet port 13b to measure a flow rate of coolant supplied to the passage 13c.

A flow rate of coolant at the inlet port 13a measured by the flowmeter 32 is transmitted to the control unit 30.

The control unit 30 includes a CPU (not illustrated) and a memory storing a recipe (not illustrated), and controls an operating frequency of the pump 22 and openings of the valve A 60 and the valve B 62 in accordance with a procedure described in the recipe.

[Flow Rate Control]

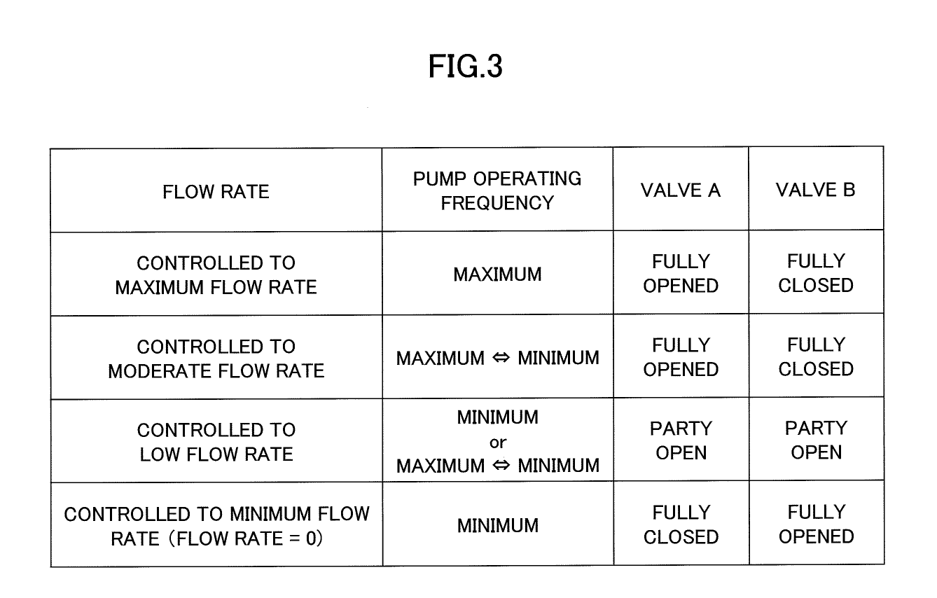

Next, a concept of coolant flow rate control will be described with reference to FIGS. 1A to 3. FIG. 1A illustrates a control state of the flow rate control system 5 in which coolant is caused to flow through the passage 13c at a maximum flow rate, FIG. 1B illustrates a control state of the flow rate control system 5 in which coolant is caused to flow through the passage 13c at a moderate flow rate, FIG. 2A illustrates a control state of the flow rate control system 5 in which coolant is caused to flow through the passage 13c at a low flow rate, and FIG. 2B illustrates a control state of the flow rate control system 5 in which coolant is caused to flow through the passage 13c at a minimum flow rate (flow rate=0), that is, a state in which coolant is not caused to flow through the passage 13c. For each of the control state of the flow rate control system 5, an example of an operating frequency, a state of the valve A 60, and a state of the valve B 62 is illustrated in a table of FIG. 3.

First, a case illustrated in FIG. 1A, in which coolant is caused to flow through the passage 13c at a maximum flow rate, will be described. If an operating frequency of the pump 22 is increased by the inverter, rotational speed of the pump 22 increases and a flow rate of coolant output from the pump 22 increases. Conversely, if an operating frequency of the pump 22 is decreased by the inverter, rotational speed of the pump 22 decreases and a flow rate of coolant output from the pump 22 decreases.

(Maximum Flow Rate Control)

Thus, in order to cause coolant to flow through the passage 13c at a maximum flow rate, as illustrated in a row of “CONTROLLED TO MAXIMUM FLOW RATE” in the table of FIG. 3, an operating frequency of the pump 22 is controlled to be at the maximum frequency. Also, the valve A 60 and the valve B 62 are controlled such that the valve A 60 is fully opened and the valve B 62 is fully closed. That is, each element in the flow rate control system 5 is controlled as illustrated in FIG. 1A. As the valve B 62 is fully closed, coolant does not flow through the bypass pipe 54. Further, as the valve A 60 is fully opened and an operating frequency of the pump 22 is set to the maximum frequency, coolant that has been output from the pump 22 at its maximum flow rate flows through the passage 13c of the base 13. Accordingly, the flow rate control system 5 can cause coolant to flow through the passage 13c at the maximum flow rate that the pump 22 can supply.

(Moderate Flow Rate Control)

In order to cause coolant to flow through the passage 13c at a moderate flow rate, as illustrated in a row of “CONTROLLED TO MODERATE FLOW RATE” in the table of FIG. 3, an operating frequency of the pump 22 is controlled at a range lower than the maximum frequency and higher than the minimum frequency. In a case in which an operating frequency of the pump 22 is controlled within this range, as the operating frequency increases, a flow rate of coolant output from the pump 22 increases. Also, as the operating frequency is decreased, a flow rate of coolant output from the pump 22 is reduced.

In a case in which a flow rate is controlled to be moderate, the valve A 60 and the valve B 62 are controlled such that the valve A 60 is fully opened and the valve B 62 is fully closed. That is, each of the elements in the flow rate control system 5 is controlled as illustrated in FIG. 1B. As the valve B 62 is fully closed, coolant does not flow through the bypass pipe 54. Further, as the valve A 60 is fully opened and an operating frequency of the pump 22 is set to a frequency lower than the maximum frequency and higher than the minimum frequency, the flow rate control system 5 can cause coolant to flow through the passage 13c at a moderate flow rate in accordance with the operating frequency.

Note that the aforementioned moderate flow rate represents a flow rate of coolant flowing out of the pump 22 and flowing through the passage 13c, while the valve A 60 is controlled to be fully opened, the valve B 62 is controlled to be fully closed, and an operating frequency of the pump 22 is controlled to be lower than the maximum frequency and higher than the minimum frequency.

(Low Flow Rate Control)

In order to cause coolant to flow through the passage 13c at a low flow rate, as illustrated in a row of “CONTROLLED TO LOW FLOW RATE” in the table of FIG. 3, an operating frequency of the pump 22 is controlled to the minimum frequency or to a frequency lower than the maximum frequency and higher than the minimum frequency. In a case in which coolant is caused to flow through the passage 13c at a low flow rate, openings of the valve A 60 and the valve B 62 are controlled to be a state in which the valve A 60 and the valve B 62 are less open with respect to a fully opened state but not in a fully closed state (hereinafter, the state may also be referred to as a “moderate opening” or “partly open”). That is, each of the elements in the flow rate control system 5 is controlled as illustrated in FIG. 2A. As the valve A 60 and the valve B 62 are controlled in a partly open state, coolant branches at the joint a. Specifically, approximately half of the coolant flows through the passage 13c in the base 13, and the other half flows through the bypass pipe 54. Accordingly, the flow rate control system 5 can cause coolant to flow through the passage 13c at a rate approximately half a flow rate of coolant flowing out of the pump 22 in accordance with the operating frequency.

Note that the aforementioned low flow rate represents a flow rate of coolant which is part of coolant flowing out of the pump 22 and branches at the joint a into the passage 13c, while the valve A 60 and the valve B 62 are controlled at the partly open state and an operating frequency of the pump 22 is controlled to the minimum frequency or to be lower than the maximum frequency and higher than the minimum frequency. The low flow rate is lower than the smallest value of the moderate flow rate and higher than the minimum flow rate (a state when a flow rate is zero).

In a state of a low flow rate, the valve A 60 is not made to be fully opened, and the valve B 62 is not made to be fully closed. Each of the valve A 60 and the valve B 62 is controlled at the partly open state. By controlling an opening of each of the valve A 60 and the valve B 62 at an appropriate degree, based on consideration of conductance of the pipe 50 and the bypass pipe 54 that depends on lengths of the pipe 50 and the bypass pipe 54, a ratio of a flow rate of coolant branching at the joint a toward the pipe 50 to a flow rate of coolant branching at the joint a toward the bypass pipe 54 can be appropriately controlled. Accordingly, the flow rate control system 5 can cause coolant to flow through the passage 13c at an appropriate low flow rate.

In a state of a low flow rate, openings of the valve A 60 and the valve B 62 are not required to be equal. By controlling an opening of each of the valve A 60 and the valve B 62 at an appropriate degree, a ratio of a flow rate of coolant branching (at the joint a) toward the pipe 50 can be controlled more accurately.

(Minimum Flow Rate Control)

In order to control a flow rate of coolant flowing through the passage 13c to a minimum flow rate, that is, in order not to cause coolant to flow through the passage 13c, as illustrated in a row of “CONTROLLED TO MINIMUM FLOW RATE (FLOW RATE=0)” in the table of FIG. 3, an operating frequency of the pump 22 is controlled to be at the minimum frequency. Also, the valve A 60 is fully closed and the valve B 62 is fully opened.

According to the configuration described above, coolant does not flow into the passage 13c because the valve A 60 is fully closed. Also, as the valve B 62 is fully opened and an operating frequency of the pump 22 is controlled to be at the minimum frequency, coolant that can flow out of the pump 22 at a minimum flow rate passes through the bypass pipe 54. Accordingly, a flow rate of coolant flowing through the passage 13c of the base 13 can be made to zero.

[Flow Rate Control Process]

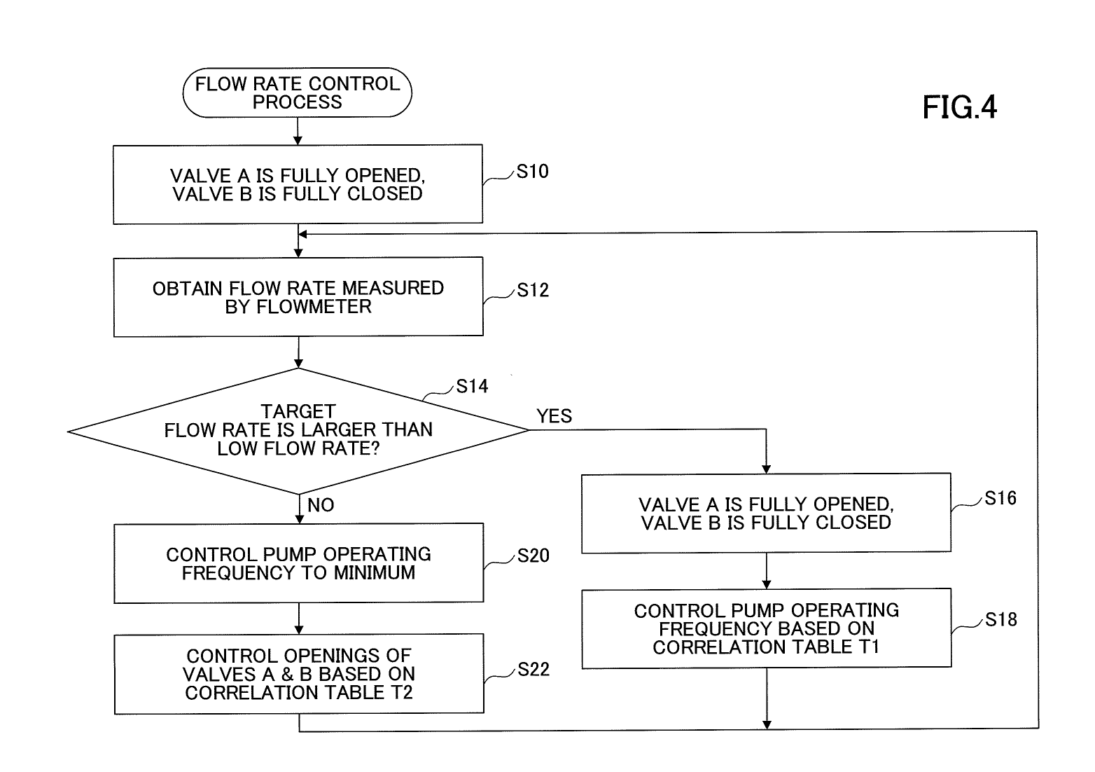

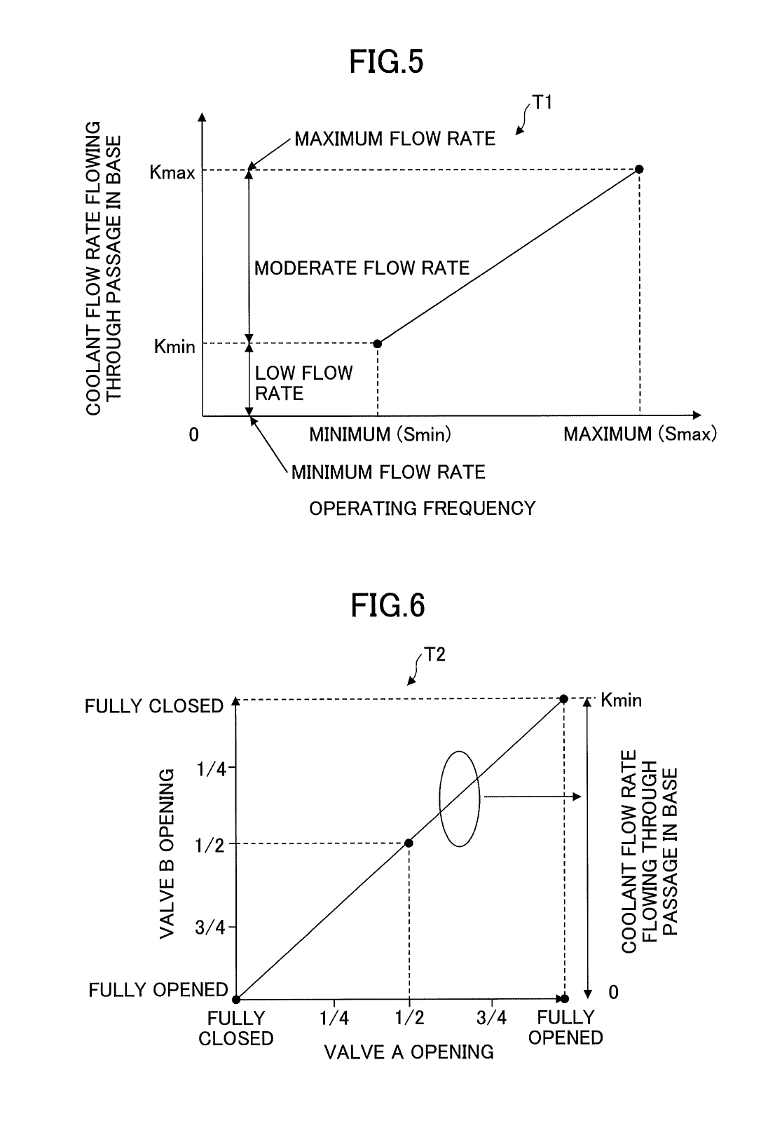

Next, a flow rate control process according to the present embodiment will be described with reference to FIGS. 4 to 6. FIG. 4 is a flowchart illustrating an example of the flow rate control process according to the present embodiment. FIG. 5 is a diagram schematically illustrating contents in a correlation table T1 storing correlation data between an operating frequency and a flow rate. FIG. 6 is a diagram schematically illustrating contents in a correlation table T2 storing correlation data between a flow rate of fluid flowing through the passage 13c and openings of the valves A 60 and B 62.

In order to obtain the correlation table T1, an experiment for measuring a flow rate of coolant flowing through the passage 13c was performed. This experiment was performed in a state in which the valve A 60 was fully opened and the valve B 62 was fully closed. In this experiment, a flow rate of coolant flowing through the passage 13c was measured by varying an operating frequency of the pump 22 from the maximum frequency (Smax) to the minimum frequency (Smin), and correlation data representing a relationship between the flow rate and the operating frequency was recorded. Note that the flow rate of coolant flowing through the passage 13c was measured by the flowmeter 32. The correlation table T1 is a table recording the correlation data which has been obtained by performing the aforementioned experiment, and the correlation table T1 is stored in a memory of the control unit 30.

A horizontal axis of a graph in FIG. 5 (in the present embodiment, the graph in FIG. 5 is referred to as “correlation table T1” for convenience) represents an operating frequency of the pump 22, and a vertical axis represents a flow rate of coolant flowing through the passage 13c of the base 13. The largest flow rate of coolant flowing through the passage 13c in a case in which an operating frequency of the pump 22 is set to the maximum frequency (Smax) is denoted by “Kmax”. The smallest flow rate of coolant flowing through the passage 13c in a case in which an operating frequency of the pump 22 is set to the minimum frequency (Smin) is denoted by “Kmin”. Also, as mentioned above, the moderate flow rate means a flow rate of coolant flowing through the passage 13c in a case in which an operating frequency of the pump 22 is controlled to be a range lower than the maximum frequency and higher than the minimum frequency.

Correlation data recorded in the correlation table T1 is not limited to the data illustrated in FIG. 5. The correlation data may be information representing a line other than the line illustrated in FIG. 5. Alternatively, the correlation data may be information representing a curve.

In order to obtain the correlation table T2, an experiment for measuring a flow rate of coolant flowing through the passage 13c when the valve A 60 and the valve B 62 are controlled in partly open states was performed, by maintaining an operating frequency of the pump 22 to the minimum frequency. In this experiment, a flow rate of coolant flowing through the passage 13c was measured by varying openings of the valves A 60 and B 62, and correlation data representing a relationship between the flow rate and the openings of the valves A 60 and B 62 was recorded. The flow rate of coolant flowing through the passage 13c was measured by the flowmeter 32. The correlation table T2 is a table recording the aforementioned correlation data, and the correlation table T2 is stored in a memory of the control unit 30.

A horizontal axis of a graph in FIG. 6 (in the present embodiment, the graph in FIG. 6 is referred to as “correlation table T2” for convenience) represents a degree of an opening of the valve A 60, and a left vertical axis represents a degree of an opening of the valve B 62. Also, a right vertical axis represents a flow rate of coolant flowing through the passage 13c.

Correlation data recorded in the correlation table T2 is not limited to the data illustrated in FIG. 6. The correlation data may be information representing a line other than the line illustrated in FIG. 6. Alternatively, the correlation data may be information representing a curve.

Correlation data recorded in the correlation table T2 is not limited to the data measured by varying openings of the valves A 60 and B 62, while an operating frequency of the pump 22 is maintained to the minimum frequency. For example, correlation data to be recorded in the correlation table T2 may be collected by varying openings of the valves A 60 and B 62, while an operating frequency of the pump 22 is maintained to one of values between the maximum frequency and the minimum frequency. Further, multiple correlation tables T2, each of which contains correlation data collected while an operating frequency of the pump 22 is maintained at a different value, may be stored in the memory of the control unit 30. In a case in which multiple correlation tables T2 are stored in the memory of the control unit 30, when the control unit 30 controls openings of the valves A 60 and B 62, the control unit 30 may select one of the correlation tables T2 corresponding to an operating frequency at which the pump 22 is operated, and the control unit 30 may control openings of the valves A 60 and B 62 by referring to the selected correlation table T2.

The flow rate control process in FIG. 4 utilizes the above described correlation tables T1 and T2. Details of the flow rate control process will be described below. When the flow rate control process is started, the control unit 30 sets the valve A 60 to a fully opened state, and sets the valve B 62 to a fully closed state (step S10). Next, the control unit 30 obtains a flow rate measured by the flowmeter 32 (step S12). Next, the control unit 30 determines whether a target flow rate (a flow rate set by the control unit 30, or by a user of the flow rate control system 5, to cause coolant to flow through the passage 13c) is larger than a low flow rate (step S14).

If it is determined at step S14 that the target flow rate is larger than the low flow rate, while the control unit 30 maintains the valve A 60 to a fully opened state, and maintains the valve B 62 to a fully closed state at step S16, the process proceeds to step S18.

At step S18, the control unit 30 controls an operating frequency of the pump 22 based on the flow rate measured by the flowmeter 32 such that a flow rate of coolant flowing through the passage 13c approximates the target flow rate. After step S18, the process reverts to step S12.

If it is determined at step S14 that the target flow rate is not larger than the low flow rate, the control unit 30 sets an operating frequency of the pump 22 to the minimum frequency (step S20). Next, the control unit 30 controls openings of the valves A 60 and B 62 based on the flow rate measured by the flowmeter 32 such that a flow rate of coolant flowing through the passage 13c approximates the target flow rate (step S22). After step S22, the process reverts to step S12.

As described above, it is possible to control a flow rate of coolant flowing through the passage 13c to the maximum flow rate (Kmax) or to the moderate flow rate illustrated in FIG. 5, by controlling an operating frequency of the pump 22 within a range between the maximum frequency and the minimum frequency while the valve A 60 is maintained to a fully opened state and the valve B 62 is maintained to a fully closed state.

However, by only controlling an operating frequency of the pump 22, a flow rate of coolant flowing through the passage 13c cannot be controlled to be lower than the moderate flow rate (that is, the low flow rate or the minimum flow rate). In the flow rate control process according to the present embodiment, the control unit 30 controls degrees of openings of the valves A 60 and B 62, in addition to control of an operating frequency of the pump 22. By controlling openings of the valves A 60 and B 62, the flow rate control system 5 can cause coolant flowing out of the pump 22 to branch to the pipe 50 and the bypass pipe 54 at the joint a, in accordance with a ratio of a degree of an opening of the valve A 60 to a degree of an opening of the valve B 62. Thus, a flow rate of coolant flowing through the passage 13c can be controlled to the low flow rate or the minimum flow rate which is smaller than Kmin (the smallest flow rate attained by controlling an operating frequency of the pump 22).

That is, by controlling openings of the valves A 60 and B 62, a lower limit of a range of a flow rate of coolant flowing through the passage 13c can be extended to a region of the low flow rate or the minimum flow rate, which would not be attainable by controlling only an operating frequency of the pump 22.

In the flow rate control process according to the present embodiment, the control unit 30 controls an operating frequency of the pump 22 and openings of the valves A 60 and B 62 with respect to a target flow rate, based on the correlation tables T1 and T2. In addition, based on a flow rate flowing through the passage 13c which is. obtained by the flowmeter 32, and based on a target flow rate, the control unit 30 controls an operating frequency of the pump 22 and openings of the valves A 60 and B 62, such that a flow rate of coolant flowing through the passage 13c approximates the target flow rate.

However, a method of controlling a flow rate is not limited to the process described above. For example, the control unit 30 may not necessarily perform feedback control of a flow rate. In this case, the control unit 30 is not required to obtain a measured result from the flowmeter 32. The control unit 30 may control an operating frequency of the pump 22 and openings of the valves A 60 and B 62 with respect to a target flow rate, based on only the correlation table T1 and the correlation table T2 (or one correlation table T2 selected from multiple correlation tables T2).

[Configuration of Temperature Control System]

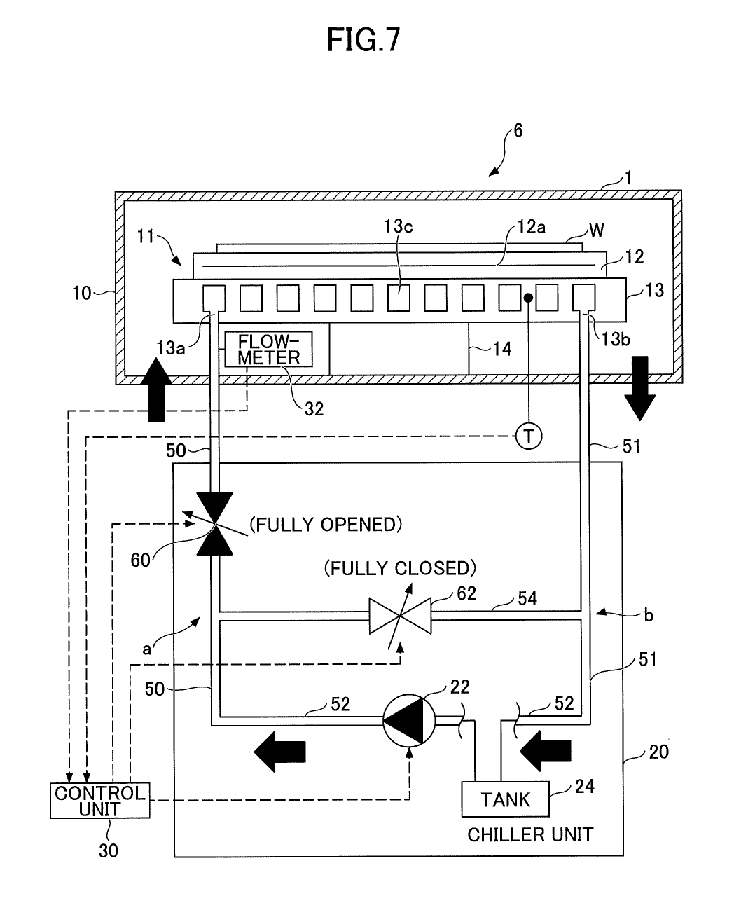

Next, an example of a configuration of a temperature control system 6 according to the embodiment will be described with reference to FIG. 7. FIG. 7 is a diagram illustrating the configuration of the temperature control system 6 according to the present embodiment. As illustrated in FIG. 7, the temperature control system 6 includes a processing apparatus 1. With respect to the configuration of the temperature control system 6, only points that differ from the flow rate control system 5 will be described, and descriptions of components which are the same as those in the flow rate control system 5 will be omitted.

The temperature control system 6 includes a processing vessel 10, a chiller unit 20, and a control unit 30. The chiller unit 20 is provided outside of the processing vessel 10. The chiller unit 20 supplies coolant (brine) which is fluid of a predetermined temperature to a passage 13c.

The chiller unit 20 includes a pump 22 and a tank 24. In the chiller unit 20, a part of a pipe 50, a part of a pipe 51, an entire pipe 52, and an entire bypass pipe 54 are provided.

In the chiller unit 20, an inverter is provided, and a flow rate of coolant flowing out of the pump 22 is controlled by the inverter varying an operating frequency of the pump 22. After the coolant is output from the pump 22, the coolant branches at the joint a, and a ratio of coolant branching toward the pipe 50 to coolant branching toward the bypass pipe 54 is controlled in accordance with openings of the valve A 60 and the valve B 62.

At the joint b, the coolant that has entered from the pipe 50 to the passage 13c and has passed through the passage 13c joins the coolant that has passed through the bypass pipe 54, and returns to the pump 22. The coolant is output from the pump 22 again, and circulates in a path from the pipe 50 to the pipe 52 via the passage 13c and the pipe 51 or a path from the pipe 50 to the pipe 52 via the bypass pipe 54 and the pipe 51.

In the processing vessel 10, a flowmeter 32 is provided in a vicinity of an inlet port 13a of the coolant. A temperature sensor T is fitted to a base 13. The temperature sensor T detects temperature of the base 13. A flow rate of the coolant at the inlet port 13a which is measured by the flowmeter 32 is transmitted to the control unit 30. Also, temperature detected by the temperature sensor T is transmitted to the control unit 30.

The control unit 30 controls an operating frequency of the pump 22, openings of the valve A 60 and the valve B 62, and a temperature of coolant in the tank 24, in accordance with a procedure described in the recipe stored in a memory.

Note that a layout of the bypass pipe 54, the valve A 60, and the valve B 62, is not limited to that illustrated in FIG. 7. The valve A 60 and the valve B 62 may be provided inside the chiller unit 20 or outside of the chiller unit 20, in accordance with a layout of the pipe 50 and the bypass pipe 54. Similarly, the pump 22 may be provided inside the chiller unit 20 or outside of the chiller unit 20.

[Temperature Control Process]

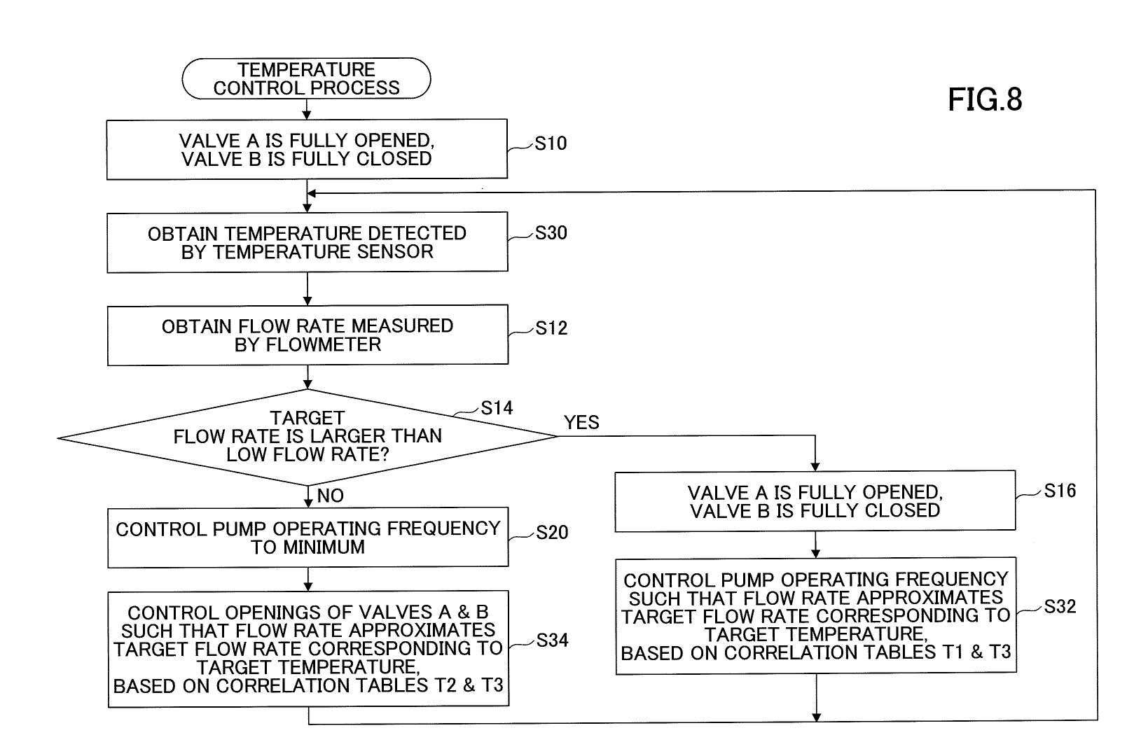

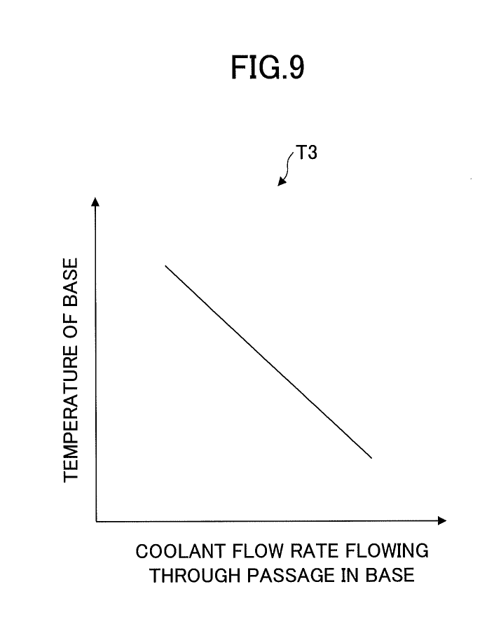

Next, a temperature control process according to the present embodiment will be described with reference to FIGS. 8 and 9. FIG. 8 is a flowchart illustrating an example of the temperature control process according to the present embodiment. FIG. 9 is a diagram schematically illustrating contents in a correlation table T3 storing correlation data between a flow rate of coolant flowing through the passage 13c and a temperature of the base 13.

The correlation table T3 is a table stored in a memory of the control unit 30, which records the aforementioned correlation data between a flow rate of coolant flowing through the passage 13c and a temperature of the base 13. The correlation data is obtained in advance, and is recorded in the correlation table T3. A flow rate of coolant flowing through the passage 13c is measured by the flowmeter 32. A temperature of the base 13 is detected by the temperature sensor T.

A horizontal axis of a graph in FIG. 9 (in the present embodiment, the graph in FIG. 9 is referred to as “correlation table T3” for convenience) represents a flow rate of coolant flowing through the passage 13c, and a vertical axis represents a temperature of the base 13. Correlation data recorded in the correlation table T3 is not limited to the data illustrated in FIG. 9. The correlation data may be information representing a line other than the line illustrated in FIG. 9. Alternatively, the correlation data may be information representing a curve.

When the temperature control process is started, the control unit 30 sets the valve A 60 to a fully opened state, and sets the valve B 62 to a fully closed state (step S10). Next, the control unit 30 obtains temperature detected by the temperature sensor T (step S30).

Next, the control unit 30 obtains a flow rate measured by the flowmeter 32 (step S12). Next, the control unit 30 determines whether a target flow rate corresponding to a target temperature (a target temperature is a temperature to which the base 13 is to be controlled. A target flow rate is a flow rate of coolant flowing through the passage 13c that is required for controlling a temperature of the base 13 to the target temperature) is larger than a low flow rate (step S14).

If it is determined at step S14 that the target flow rate is larger than the low flow rate, the process proceeds to step S32 while the control unit 30 maintains the valve A 60 to a fully opened state, and maintains the valve B 62 to a fully closed state (step S16). At step S32, the control unit 30 controls an operating frequency of the pump 22 by referring to the correlation tables T1 and T3, based on the temperature detected by the temperature sensor T and based on the flow rate measured by the flowmeter 32. Specifically, the control unit 30 controls an operating frequency of the pump 22 based on the measured temperature and the measured flow rate, such that a flow rate of coolant flowing through the passage 13c approximates the target flow rate corresponding to the target temperature, by referring to the correlation tables T1 and T3. After step S32, the process reverts to step S30.

If it is determined at step S14 that the target flow rate is not larger than the low flow rate, the control unit 30 sets an operating frequency of the pump 22 to the minimum frequency (step S20). Next, the control unit 30 controls openings of the valves A 60 and B 62 based on the temperature detected by the temperature sensor T and, based on the flow rate measured by the flowmeter 32, such that a flow rate of coolant flowing through the passage 13c approximates the target flow rate corresponding to the target temperature, by referring to the correlation tables T2 and T3 (step S34). After step S34, the process reverts to step S30.

As described above, in the temperature control process according to the present embodiment, the control unit 30 controls openings of the valves A 60 and B 62, in addition to controlling the operating frequency of the pump 22. By controlling the openings of the valves A 60 and B 62, the temperature control system 6 can cause coolant to branch to the pipe 50 and the bypass pipe 54 at the joint a, in accordance with a ratio of a degree of an opening of the valve A 60 to a degree of an opening of the valve B 62. Thus, a flow rate of coolant flowing through the passage 13c can be controlled to the low flow rate or the minimum flow rate, which is smaller than Kmin (the smallest flow rate attained by controlling an operating frequency of the pump 22).

That is, by controlling not only an operating frequency of the pump 22 but also openings of the valves A 60 and B 62, a lower limit of a range of a flow rate of coolant flowing through the passage 13c can be extended to a region of the low flow rate or the minimum flow rate (flow rate=0), which cannot be attained only by controlling an operating frequency of the pump 22. That is, a lower limit on a flow rate of coolant that would need to be passed through the passage 13c can be eliminated. As a result, a restriction on a range of a heat exchange amount between coolant and the base 13 is eliminated, and accuracy of temperature control of the base 13 can be improved. Thus, a temperature of a wafer W can be adjusted more accurately.

Also, the following additional effect can be achieved. As a flow rate of coolant flowing through the passage 13c decreases, friction between the passage 13c and the coolant decreases, and pressure drop in the passage 13c, which is a loss of pressure for expelling fluid, also decreases. Therefore, according to the present embodiment, as a lower limit of a range of flow rate control is extended, use of coolant under an environment with small pressure drop is enabled.

Note that a method of controlling temperature (temperature control process) is not limited to the process described above. Similar to the aforementioned flow rate control process, the control unit 30 may not perform feedback control of a temperature or a flow rate. In this case, the control unit 30 is not required to obtain a temperature or a flow rate from the temperature sensor T or the flowmeter 32. The control unit 30 may control an operating frequency of the pump 22 and openings of the valves A 60 and B 62 based on only the correlation tables T1, T2, and T3.

In the above embodiment, the flow rate control method, the temperature control method, and the processing apparatus have been described. However, a flow rate control method, a temperature control method, and a processing apparatus according to the present disclosure are not limited to the embodiment described above. Various changes or enhancements can be made thereto within the scope of the present disclosure. Matters described in the above embodiment may be combined unless inconsistency occurs.

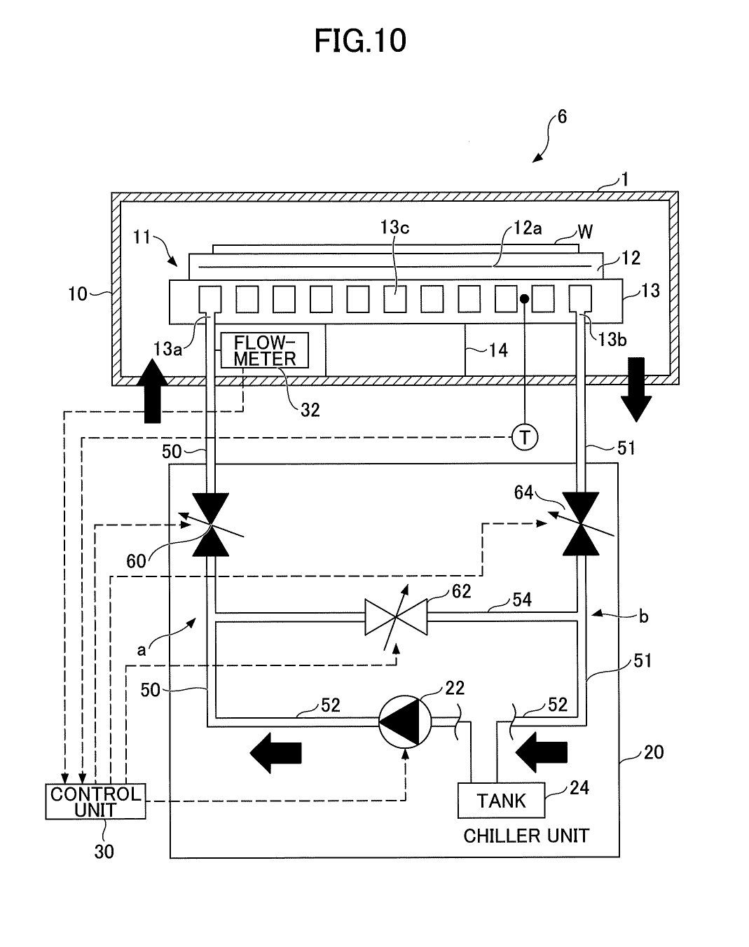

For example, a configuration of a processing apparatus is not limited to the aforementioned configurations of the processing apparatus 1, the flow rate control system 5, and the temperature control system 6. A processing apparatus may be configured as illustrated in FIG. 10. FIG. 10 is an example of a processing apparatus 1 and a temperature control system 6 according to a modified example of the above embodiment.

A configuration of the processing apparatus 1 (or the temperature control system 6) according to the modified example differs from that in FIG. 1 (or FIG. 7) in that a valve C 64 is provided at a pipe 51 provided at a downstream side. The valve C 64 is provided at a location closer to an outlet port 13b of a passage 13c relative to a joint b of the pipe 51. In the modified example, the valve C 64 prevents coolant, which flows out of a bypass pipe 54 and flows into the pipe 51 at the joint b, from flowing toward the passage 13c of the base 13. Note that the valve C 64 is an example of a second valve provided at a second pipe.

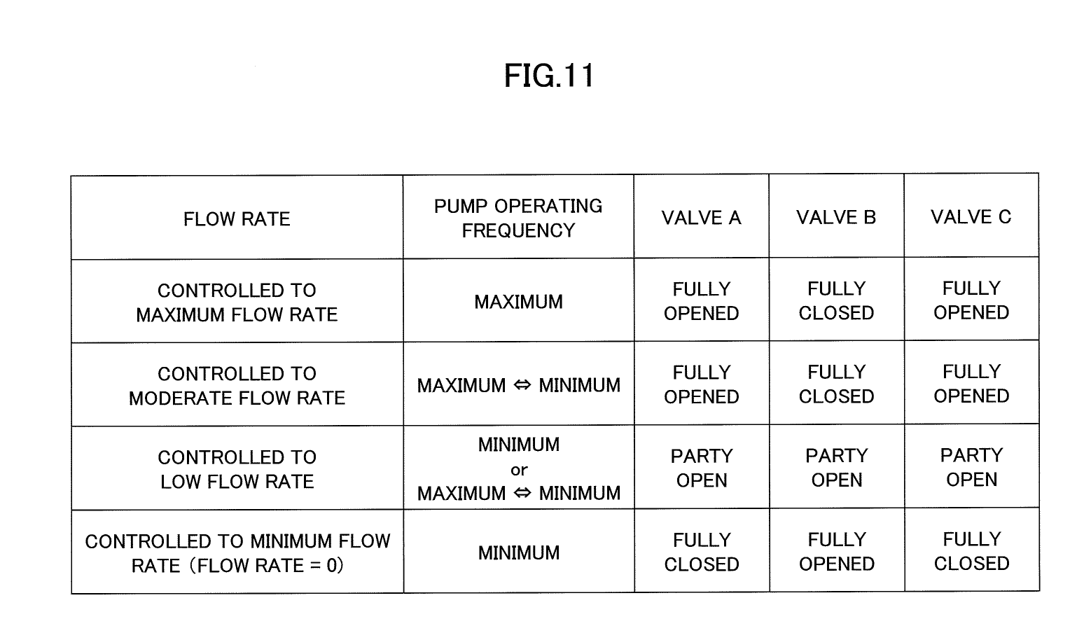

An example of an operating frequency and states of the valves in a flow rate control process according to the modified example is illustrated in FIG. 11. In the modified example, when a flow rate of the passage 13c is controlled to a “maximum flow rate”, an operating frequency of a pump 22 is controlled to be the maximum frequency. In addition, a valve A 60 is controlled to be a fully opened state, a valve B 62 is controlled to be a fully closed state, and the valve C 64 is controlled to be a fully opened state. In this case, coolant that flows out of the pump 22 circulates in a path from the pipe 50 to a tank 24 via the passage 13c and the pipe 51.

When a flow rate of the passage 13c is controlled to a “moderate flow rate”, an operating frequency of a pump 22 is controlled at a frequency lower than the maximum frequency and higher than the minimum frequency. Also, the valve A 60 is controlled to be a fully opened state, the valve B 62 is controlled to be a fully closed state, and the valve C 64 is controlled to be a fully opened state. In this case, coolant that flows out of the pump 22 circulates in a path from the pipe 50 to a tank 24 via the passage 13c and the pipe 51.

When a flow rate of the passage 13c is controlled to a “low flow rate”, an operating frequency of a pump 22 is controlled to the minimum frequency or to a frequency lower than the maximum frequency and higher than the minimum frequency. Also, openings of the valve A 60, the valve B 62, and the valve C 64 are controlled to be partly open. In this case, coolant that flows out of the pump 22 circulates in a path from the pipe 50 to the pipe 51 via the passage 13c, or in a path from the pipe 50 to the pipe 51 via the bypass pipe 54.

When a flow rate of the passage 13c is controlled to a “minimum flow rate (0)”, an operating frequency of a pump 22 is controlled to the minimum frequency. In addition, a valve A 60 is controlled to be a fully closed state, a valve B 62 is controlled to be a fully opened state, and the valve C 64 is controlled to be a fully closed state. In this case, coolant that flows out of the pump 22 circulates in a path from the pipe 50 to the pipe 51 via the bypass pipe 54.

According to the modified example, by providing the valve C 64 at the pipe 51 provided at a downstream side, coolant that flows out of the bypass pipe 54 and that joins another coolant in the pipe 51 at the joint b is prevented from flowing toward the passage 13c of the base 13.

Note that the aforementioned coolant that is output from the pump 22 is controlled at a predetermined (constant) temperature by the chiller unit 20. The coolant is an example of a heating medium. Thus, when the heating medium passes through the passage 13c, the stage 11 is cooled or heated in accordance with a temperature of the heating medium. As the heating medium flowing through the passage 13c is fluid for controlling a temperature of the stage 11, the heating medium may be liquid or gas. Further, the chiller unit 20 is an example of a temperature control unit configured to control a temperature of the stage 11.

The processing apparatus according to the present disclosure may be a plasma processing apparatus applying a predetermined process by action of plasma. Examples of the plasma processing apparatuses includes a capacitively coupled plasma (CCP) type, an inductively coupled plasma (ICP) type, a radial line slot antenna type, an electron cyclotron resonance plasma (ECR) type, and a helicon wave plasma (HWP) type.

Alternatively, the processing apparatus according to the present disclosure is not limited to a plasma processing apparatus. The processing apparatus according to the present disclosure may be a non-plasma processing apparatus. For example, the processing apparatus according to the present disclosure may be a processing apparatus applying a predetermined process by using heat.

Further, an object to which the temperature control method according to the present disclosure can be applied is not limited to a base.

The temperature control method according to the present disclosure can be applied to any members in which passages (fluid passages) are formed. For example, a passage may be formed in an upper electrode or the processing vessel of the processing apparatus according to the present embodiment, and temperature of the upper electrode or the processing vessel may be controlled by controlling a flow rate of fluid flowing through the passage.

What is claimed is:

1. A method of controlling a flow rate of fluid flowing through a passage formed in a member of a system, the system including
the member,
a first pipe connected to one side of the passage,
a second pipe connected to another side of the passage,
a third pipe connecting the first pipe and the second pipe at a side opposite the passage,
a bypass pipe connecting the first pipe and the second pipe at a location closer to the member relative to the third pipe,
a first valve provided at the first pipe,
a bypass valve provided at the bypass pipe, and
a pump provided at the third pipe, the pump being configured to supply the fluid to the passage;
the method comprising:
controlling the first valve;
controlling the bypass valve; and
controlling an operating frequency of the pump.

2. The method according to claim 1, wherein the first pipe is provided at an upstream side of the passage.

3. The method according to claim 1, wherein,
in the controlling of the first valve, a degree of an opening of the first valve is controlled to be smaller relative to a fully opened state, and
in the controlling of the bypass valve, a degree of an opening of the bypass valve is controlled to be larger relative to a fully closed state.

4. The method according to claim 3, the system further including a correlation table recording data representing a relationship between the flow rate of the fluid flowing through the passage and a set of the opening of the first valve and the opening of the bypass valve, wherein,
in a case in which the operating frequency of the pump is controlled to a minimum frequency in the controlling of the operating frequency of the pump,
the controlling of the first valve includes controlling the opening of the first valve in accordance with the flow rate, by referring to the correlation table, and
the controlling of the bypass valve includes controlling the opening of the bypass valve in accordance with the flow rate, by referring to the correlation table.

5. The method according to claim 1, further comprising
controlling a second valve provided at the second pipe.

6. The method according to claim 5, wherein, in the controlling of the second valve, a degree of an opening of the second valve is controlled to be smaller relative to a fully opened state.

7. The method according to claim 1, wherein the first pipe is provided at a location closer to the member relative to the bypass pipe.

8. The method according to claim 5,
wherein the second valve is provided at a location closer to the member relative to the bypass pipe.

9. A method of controlling a temperature of a member in a system, the system including
the member,
a passage formed in the member,
a first pipe connected to one side of the passage,
a second pipe connected to another side of the passage,
a third pipe connecting the first pipe and the second pipe at a side opposite the passage,
a bypass pipe connecting the first pipe and the second pipe at a location closer to the member relative to the third pipe,
a first valve provided at the first pipe,
a bypass valve provided at the bypass pipe,
a pump provided at the third pipe, the pump being configured to supply fluid to the passage, and
a temperature control unit;
the method comprising:
controlling the first valve;
controlling the bypass valve;
controlling an operating frequency of the pump; and
controlling a temperature of the fluid to be output from the pump by the temperature control unit.

10. The method according to claim 9, wherein the first pipe is provided at an upstream side of the passage.

11. The method according to claim 10, wherein
the pump is provided in the temperature control unit or outside of the temperature control unit, and
the controlling of the operating frequency of the pump is performed by an inverter provided in the temperature control unit.

12. The method according to claim 10, wherein the temperature control unit is a chiller unit.

13. The method according to claim 12, wherein,
in the controlling of the first valve, a degree of an opening of the first valve is controlled to be smaller relative to a fully opened state, and
in the controlling of the bypass valve, a degree of an opening of the bypass valve is controlled to be larger relative to a fully closed state.

14. The method according to claim 13, the system further including
a first correlation table recording data representing a relationship between the flow rate of the fluid flowing through the passage and a set of the opening of the first valve and the opening of the bypass valve, and
a second correlation table recording data representing a relationship between the flow rate of the fluid flowing through the passage and the temperature of the member; wherein,
in a case in which the operating frequency of the pump is controlled to a minimum frequency in the controlling of the operating frequency of the pump,
the controlling of the first valve includes controlling the opening of the first valve in accordance with the flow rate, by referring to the first correlation table and the second correlation table, and
the controlling of the bypass valve includes controlling the opening of the bypass valve in accordance with the flow rate, by referring to the first correlation table and the second correlation table.

15. The method according to claim 9, further comprising
controlling a second valve provided at the second pipe.

16. The method according to claim 15, wherein, in the controlling of the second valve, a degree of an opening of the second valve is controlled to be smaller relative to a fully opened state.

17. The method according to claim 9, wherein the first pipe is provided at a location closer to the member relative to the bypass pipe.

18. A processing apparatus comprising:
a processing vessel;
a member provided in the processing vessel;
a passage formed in the member;
a first pipe connected to one side of the passage;
a second pipe connected to another side of the passage;
a third pipe connecting the first pipe and the second pipe at a side opposite the passage;
a bypass pipe connecting the first pipe and the second pipe at a location closer to the member relative to the third pipe;
a first valve provided at the first pipe;
a bypass valve provided at the bypass pipe;
a pump provided at the third pipe, the pump being configured to supply fluid to the passage; and
a control unit configured to control the first valve, the bypass valve, and an operating frequency of the pump.

19. The processing apparatus according to claim 18, further comprising a second valve provided at the second pipe.

20. The processing apparatus according to claim 18, further comprising a temperature control unit controlled by the control unit.
